(19) United States
(12) Patent Application Publication
(10) Pub. No.: US 2025/0300110 A1
(43) Pub. Date: Sep. 25, 2025

(54) SEMICONDUCTOR DEVICE AND MANUFACTURING METHOD OF SEMICONDUCTOR DEVICE

(71) Applicant: SK hynix Inc., Gyeonggi-do (KR)

(72) Inventor: Heon Yong CHANG, Gyeonggi-do (KR)

(21) Appl. No.: 18/749,615

(22) Filed: Jun. 21, 2024

(30) Foreign Application Priority Data
Mar. 21, 2024 (KR) 10-2024-0039163

(51) Int. Cl. H01L 23/00; H01L 21/48; H01L 23/31; H01L 23/522; H01L 23/528; H01L 23/58; H01L 25/065; H10B 80/00

(52) U.S. Cl. CPC H01L 24/08; H01L 21/486; H01L 23/3121; H01L 23/5226; H01L 23/5283; H01L 23/585; H01L 25/0655; H01L 2224/08225; H01L 2924/1815; H10B 80/00

(57) ABSTRACT

A semiconductor device may include a substrate including a chip region and a sealing region surrounding the chip region; first bonding pads located on the substrate; second bonding pads located in the chip region and bonded to the first bonding pads; an interlayer insulating layer located on the first bonding pads; and contact rings located in the sealing region, extending through the interlayer insulating layer and connected to the first bonding pads, and each having a closed curve shape.

### CROSS-REFERENCE TO RELATED APPLICATION

This application claims priority under 35 U.S.C. § 119 to Korean Patent Application No. 10-2024-0039163 filed on Mar. 21, 2024, which is incorporated herein by reference in its entirety.

### BACKGROUND

### 1. Technical Field

Embodiments of the present disclosure relate to an electronic device and a manufacturing method of the electronic device, and more particularly, to a semiconductor device and a manufacturing method of the semiconductor device.

### 2. Related Art

The degree of integration of a semiconductor device is mainly determined by an area occupied by a unit memory cell. Recently, as the improvement in the degree of integration of a semiconductor device for forming memory cells in a single layer on a substrate reaches a limit, a three-dimensional semiconductor device for stacking memory cells on a substrate has been proposed. Furthermore, in order to improve the operational reliability of such a semiconductor device, various structures and manufacturing methods have been developed.

### SUMMARY

In an embodiment of the present disclosure, a semiconductor device may include a substrate including a chip region and a sealing region surrounding the chip region; first bonding pads located over the substrate; second bonding pads located in the chip region and bonded to the first bonding pads; an interlayer insulating layer located on the first bonding pads; and contact rings located in the sealing region, extending through the interlayer insulating layer and connected to the first bonding pads, and each having a closed curve shape.

In an embodiment of the present disclosure, a manufacturing method of a semiconductor device may include: forming a first wafer including a peripheral circuit region and a first sealing region surrounding the peripheral circuit region and including first bonding pads located in the peripheral circuit region and the first sealing region; forming a second wafer including a cell region and a second sealing region surrounding the cell region and including an interlayer insulating layer located in the cell region and the second sealing region and second bonding pads located in the cell region; bonding the first wafer and the second wafer to each other so that the peripheral circuit region and the cell region face each other and the first sealing region and the second sealing region face each other; forming first openings through the interlayer insulating layer of the second sealing region, the first openings exposing the first bonding pads of the first sealing region and each having a closed curve shape; and forming contact rings in the first openings.

### BRIEF DESCRIPTION OF THE DRAWINGS

FIGS. 1A and 1B are diagrams for describing a semiconductor device in accordance with an embodiment of the present disclosure.

FIG. 2 is a flowchart of a manufacturing method of a semiconductor device in accordance with an embodiment of the present disclosure.

FIGS. 3A, 4A, 5A, and 6A, FIGS. 3B, 4B, 5B, and 6B, and FIG. 7 are diagrams for describing a manufacturing method of a semiconductor device in accordance with an embodiment of the present disclosure.

### DETAILED DESCRIPTION

Various embodiments of the present disclosure are directed to a semiconductor device having a stable structure and improved characteristics and a manufacturing method of the semiconductor device.

According to the present technology, it is possible to provide a semiconductor device having a stable structure and improved reliability.

Hereafter, embodiments in accordance with the technical spirit of the present disclosure will be described with reference to the accompanying drawings.

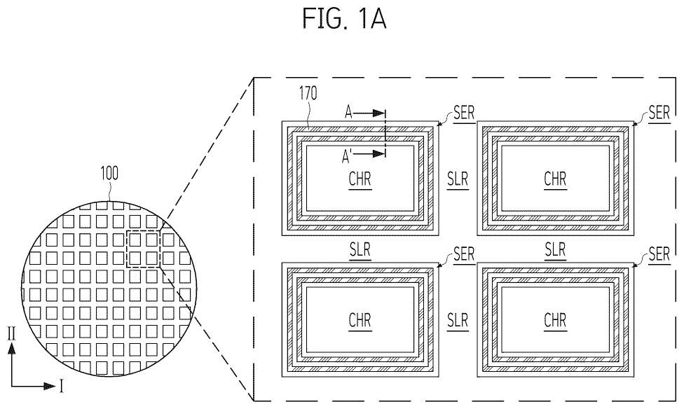

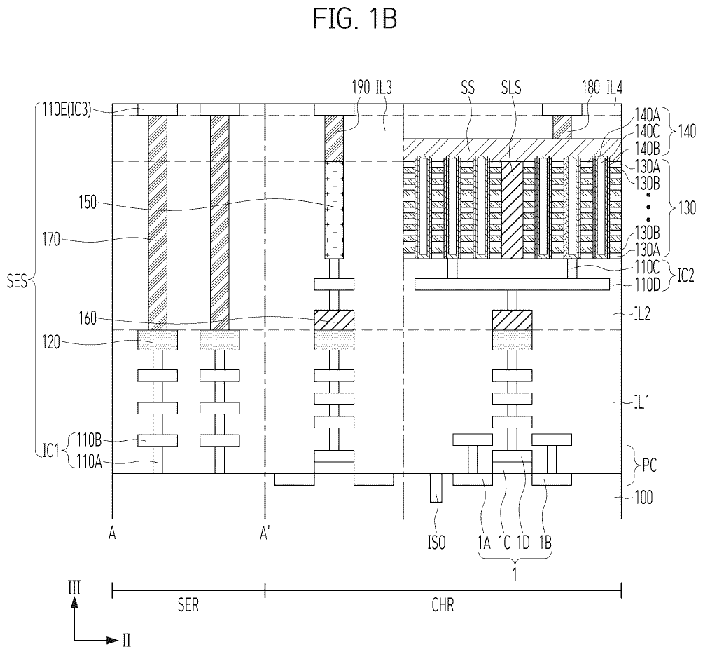

FIGS. 1A and 1B are diagrams for describing a semiconductor device in accordance with an embodiment of the present disclosure.

Referring to FIG. 1A, the semiconductor device may include a substrate 100 including a plurality of spaced apart chip regions CHR. The substrate may further include sealing regions SER, each sealing region SER surrounding a corresponding chip region CHR in a one to one correspondence. The substrate 100 may further include a scribe lane region SLR disposed between the sealing regions SER and also around the totality of the sealing regions SER forming an outer frame for the semiconductor device.

The chip regions CHR are regions where semiconductor chips are formed. The semiconductor chips may be repeatedly formed on the substrate 100 for example in multiple rows and columns. For example, the chip regions CHR may be arranged in rows extending in a first direction I and columns extending in a second direction II intersecting the first direction I. For example, the first and second directions may be orthogonal to each other. However, arrangement of the chip regions CHR in the semiconductor device may vary.

The scribe lane region SLR may be located between the chip regions CHR and also between the sealing regions SER, with the sealing regions SER being disposed between the scribe lane region SLR and the chip regions CHP as shown in FIG. 1A. The scribe lane region SLR is the region where the cutting occurs in the dicing process for separating the semiconductor chip regions CHR from each other. The semiconductor chip regions CHR are separated from each other by cutting the substrate 100 along the scribe lane region SLR.

The sealing regions SER may surround the chip regions CHR, respectively. A sealing structure SES may be located in each of the sealing regions SER as shown in FIG. 1B. The sealing structures SES protect their respective chip regions CHR from external contamination including, for example, moisture contamination. In addition, the sealing structure SES may prevent or reduce damage to their respective chip regions CHR during the dicing process of cutting the substrate 100 along the scribe lane region SLR.

Referring now to FIG. 1B, the semiconductor device may include the substrate 100, a first interconnection structure IC1, a second interconnection structure IC2, a third interconnection structure IC3, a first bonding pad 120, a gate structure 130, channel structures 140, a contact plug 150, a second bonding pad 160, a contact ring 170, a first contact via 180, a second contact via 190, and a source structure SS. The semiconductor device may further include at least one of a peripheral circuit PC, a slit structure SLS, an element isolation layer ISO, a first interlayer insulating layer IL1, a second interlayer insulating layer IL2, a third interlayer insulating layer IL3, and a fourth interlayer insulating layer IL4.

The peripheral circuit PC may be located on the substrate 100. For example, the peripheral circuit PC may be located in the chip region CHR of the substrate 100. The peripheral circuit PC may include a transistor 1. The transistor 1 may include junctions 1A and 1B, a gate electrode 1D, and a gate insulating layer 1C. Here, the gate insulating layer 1C may be located between the gate electrode 1D and the substrate 100. The element isolation layer ISO may be located in the substrate 100, and an active region of the transistor 1 may be defined by the element isolation layer ISO.

The first interconnection structure IC1 may be located on the substrate 100. For example, the first interconnection structure IC1 may be located in at least one of the chip region CHR, the sealing region SER, and the scribe lane region SLR. The first interconnection structure IC1 may be located in the first interlayer insulating layer IL1. Here, the first interlayer insulating layer IL1 may be located on the substrate 100. The first interconnection structure IC1 may include first vias 110A extending vertically, i.e., perpendicularly to the top plane of the substrate 100 and first wiring lines 110B extending horizontally, i.e., parallel to the top plane of the substrate 100.

The first interconnection structure IC1 may be connected to the peripheral circuit PC. For example, at least one of the first vias 110A may be connected to the transistor 1. At least one of the first vias 110A may connect the first wiring lines 110B to each other. The first interconnection structure IC1 may be in contact with the substrate 100. For example, at least one of the first vias 110A may be in contact with the substrate 100. The first wiring lines 110B may connect the first vias 110A to each other. The first interconnection structure IC1 may include a conductive material such as, for example, tungsten, copper, or aluminum. The first interlayer insulating layer IL1 may include an insulating material such, as for example, an oxide or nitride.

The first bonding pads 120 may be located over the substrate 100. For example, the first bonding pads 120 may be located in the chip region CHR and the sealing region SER. The first bonding pads 120 may be connected to the peripheral circuit PC through the first interconnection structure IC1 in the chip region CHR. The first bonding pads 120 may be connected to the substrate 100 through the first interconnection structure IC1 in the sealing region SER. The first bonding pads 120 may each include a conductive material such, as for example, copper.

The second bonding pads 160 may be located on the first bonding pads 120. For example, the second bonding pads 160 may be located in the chip region CHR, and may be bonded to the first bonding pads 120. The second bonding pads 160 may be located in the second interlayer insulating layer IL2. Here, the second interlayer insulating layer IL2 may be located on the first interlayer insulating layer IL1. The second bonding pads 160 may not exist in the sealing region SER. The second bonding pads 160 may each include a conductive material such, as for example, copper. The second interlayer insulating layer IL2 may include an insulating material such, as for example, an oxide or nitride.

In a process of manufacturing the semiconductor device, the first bonding pads 120 and the second bonding pads 160 may be bonded to each other. The first bonding pads 120 and the second bonding pads 160 may each include copper, and the first bonding pads 120 and the second bonding pads 160 may expand in a process of bonding the first bonding pads 120 and the second bonding pads 160 to each other, such that a delamination phenomenon may occur at a bonding interface.

Bonding force at the bonding interface may become greater as an area occupied by the first and second interlayer insulating layers IL1 and IL2 becomes greater. For example, the bonding force at the bonding interface may become greater as the area occupied by the first and second interlayer insulating layers IL1 and IL2 becomes greater than an area occupied by the first bonding pads 120 and the second bonding pads 160 each including copper.

According to an embodiment of the present disclosure, the second bonding pads 160 may not exist in the sealing region SER. The area occupied by the first and second interlayer insulating layers IL1 and IL2 in the sealing region SER may be relatively greater than that in the chip region CHR, and the bonding force at the bonding interface in the sealing region SER may be relatively greater than that in the chip region CHR. Accordingly, even though the first bonding pads 120 expand in the sealing region SER, the delamination phenomenon may not occur at the bonding interface.

The gate structure 130 may be located in the chip region CHR. The gate structure 130 may be located over the peripheral circuit PC. The gate structure 130 may include insulating layers 130A and conductive layers 130B that are alternately stacked. The insulating layers 130A may each include an insulating material such as, for example, an oxide, and the conductive layers 130B may each include a conductive material such as, for example, polysilicon, or molybdenum. The channel structures 140 may extend through the gate structure 130. Each of the channel structures 140 may include at least one of a channel layer 140A, a memory layer 140B surrounding the channel layer 140A, and an insulating core 140C located in the channel layer 140A. The slit structure SLS may extend through the gate structure 130. The slit structure SLS may include an insulating material, a conductive material, a semiconductor material, or the like.

The conductive layers 130B may be gate lines such as source select lines, word lines, or drain select lines. Source select transistors, memory cells, or drain select transistors may be located in regions where the channel structures 140 and the conductive layers 130B intersect each other. As an example, at least one source select transistor, a plurality of memory cells, and at least one drain select transistor that are stacked along the channel structure 140 may constitute one memory string.

The source structure SS may be located on the gate structure 130. The source structure SS may be located over the second bonding pads 160. The source structure SS may be connected to the channel structures 140. For example, the source structure SS may be connected to the channel layers 140A of the channel structures 140.

The contact plug 150 may be located on the peripheral circuit PC. The contact plug 150 may be located in the second interlayer insulating layer IL2. The contact plug 150 may be electrically connected to the peripheral circuit PC. For example, the contact plug 150 may be electrically connected to the peripheral circuit PC through the second bonding pad 160 and the first bonding pad 120. The contact plug 150 may include a conductive material such as, for example, tungsten, copper, or aluminum.

The second interconnection structure IC2 may be located over the first interconnection structure IC1. The second interconnection structure IC2 may be located in the second interlayer insulating layer IL2. The second interconnection structure IC2 may include second vias 110C extending vertically in the third direction III and second wiring lines 110D extending in the second direction II. At least one of the second vias 110C may be connected to the channel structures 140. At least one of the second vias 110C may be connected to the contact plug 150. The second wiring lines 110D may be connected to at least one of the second vias 110C. The second interconnection structure IC2 may include a conductive material such as, for example, tungsten, copper, or aluminum.

The contact ring 170 may be located over the substrate 100. For example, the contact ring 170 may be located in the sealing region SER of the substrate 100. The contact rings 170 may extend through the second interlayer insulating layer IL2 and be connected to the first bonding pads 120. The contact ring 170 may have a closed curve shape surrounding the chip region CHR along the sealing region SER. The contact ring 170 may include a conductive material such as, for example, tungsten, copper, or aluminum.

The first contact via 180 may be located on the source structure SS. The first contact via 180 may be located in the third interlayer insulating layer IL3. Here, the third interlayer insulating layer IL3 may include an insulating material such, as for example, an oxide or nitride. An uppermost surface of the first contact via 180 may be located at the same or substantially the same level as an uppermost surface of the contact ring 170. The first contact via 180 may include the same or substantially the same material as the contact ring 170. For example, the first contact via 180 may include a conductive material such as, for example, tungsten, copper, or aluminum.

The second contact via 190 may be located on the contact plug 150. The second contact via 190 may have the same cross-section as the contact plug 150. The second contact via 190 may be located in the third interlayer insulating layer IL3. An uppermost surface of the second contact via 190 may be located at the same or substantially the same level as the uppermost surface of the contact ring 170. The second contact via 190 may include the same or substantially the same material as the contact ring 170. For example, the second contact via 190 may include a conductive material such as, for example, tungsten, copper, or aluminum.

The third interconnection structure IC3 may be located over the second interconnection structure IC2. The third interconnection structure IC3 may be located in the fourth interlayer insulating layer IL4. Here, the fourth interlayer insulating layer IL4 may be located on the third interlayer insulating layer IL3, and may include an insulating material such, as for example, an oxide or nitride. The third interconnection structure IC3 may include horizontally extending third wiring lines 110E. However, the third interconnection structure IC3 is not limited thereto, and may further include third vias (NOT SHOWN). At least one of the third wiring lines 110E may be located on the contact ring 170. At least one of the third wiring lines 110E may be connected to the first contact via 180. At least one of the third wiring lines 110E may be connected to the second contact via 190. The third interconnection structure IC3 may include a conductive material such as, for example, tungsten, copper, or aluminum.

The third interconnection structure IC3, the contact ring 170, the first bonding pad 120, and the first interconnection structure IC1 of the sealing region SER may constitute the sealing structure SES. The sealing structure SES may protect the chip region CHR from external contamination or moisture. In addition, the sealing structure SES may prevent or reduce the occurrence of a crack in each of the chip regions CHR in the process of cutting the substrate 100 along the scribe lane region SLR.

According to the structure described above, the semiconductor device may include the contact ring 170 having the closed curve shape surrounding the chip region CHR along the sealing region SER of the substrate 100. In addition, the semiconductor device may include the sealing structure SES including the contact ring 170, the first interconnection structure IC1, the third interconnection structure IC3, and the first bonding pad 120. The sealing structure SES may prevent or reduce damage to the chip region CHR from external shock, contamination, or moisture in the process of manufacturing the semiconductor device.

In addition, the second bonding pads 160, according to an embodiment of the present disclosure, may not be present in the sealing region SER, and, thus, an area occupied by the first and second interlayer insulating layers IL1 and IL2 in the sealing region SER may be relatively greater than that in the chip region CHR. Accordingly, the delamination phenomenon may be prevented from occurring during the bonding of the first and second bonding pads 120 and 160.

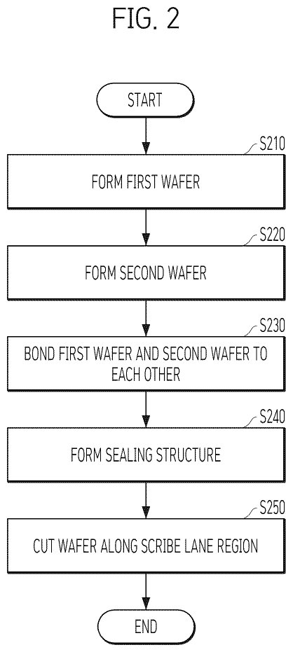

FIG. 2 is a flowchart of a manufacturing method of a semiconductor device in accordance with an embodiment of the present disclosure. Hereinafter, any content overlapping with the previously described content may be omitted.

Referring to FIG. 2, the method includes forming first and second wafers according to operations S210, and S220, respectively, then bonding the first and second wafers to each other according to operation S230, then forming a sealing structure according to operation S240, and cutting the formed wafer along a scribe lane region according to operation S250.

More specifically, the first wafer may be formed to include a peripheral circuit region and a first sealing region surrounding the peripheral circuit region (S210). Also, a peripheral circuit may be formed in the peripheral circuit region and first bonding pads may be formed in the peripheral circuit region and the first sealing region. The second wafer may be formed to include a cell region and a

second sealing region surrounding the cell region (S220). A gate structure and channel structures extending vertically through the gate structure may be formed in the cell region. An interlayer insulating layer may be formed in the cell region and the second sealing region. A contact plug may be formed in the cell region, and second bonding pads may be formed.

Subsequently, the first wafer and the second wafer are bonded to each other (S230). For example, the first wafer and the second wafer may be bonded to each other so that the peripheral circuit region and the cell region face each other and the first sealing region and the second sealing region face each other. The first bonding pads of the peripheral circuit region and the second bonding pads of the cell region may be bonded to each other. The first bonding pads of the first sealing region and the interlayer insulating layer of the second sealing region may be bonded to each other.

Subsequently, sealing structures may be formed (S240). For example, contact rings extending vertically through the interlayer insulating layer of the second sealing region and connected to the first bonding pads of the first sealing region may be formed. The contact ring may be formed in a closed curve shape surrounding the peripheral circuit region and the cell region. The contact ring and a third interconnection structure of the second sealing region may constitute a sealing structure together with the first bonding pads and a first interconnection structure of the first sealing region. The sealing structure may protect the peripheral circuit region and the cell region from external contamination or moisture.

Subsequently, the wafer may be cut along a scribe lane region (S250). When the wafer is cut, the peripheral circuit region and the cell region may be damaged. The sealing structures may prevent or reduce damage to the peripheral circuit region and the cell region in a process of cutting the wafer.

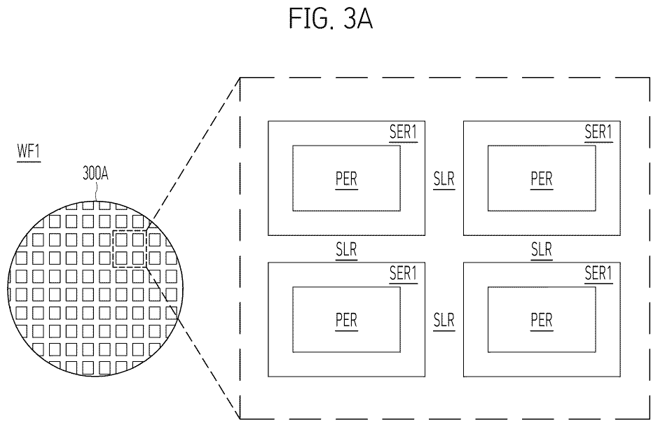

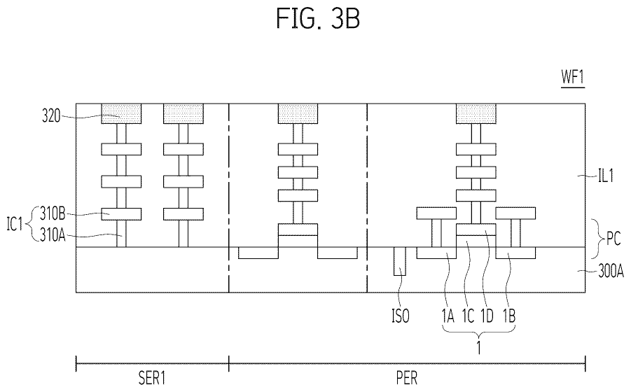

FIGS. 3A, 4A, 5A, and 6A, FIGS. 3B, 4B, 5B, and 6B, and FIG. 7 are diagrams for describing a manufacturing method of a semiconductor device in accordance with an embodiment of the present disclosure. Hereinafter, any content overlapping with the previously described content may be omitted.

Referring to FIGS. 3A and 3B, a first wafer WF1 may be formed including peripheral circuit regions PER and first sealing regions SER1 surrounding the peripheral circuit regions PER. The first wafer WF1 may further include a scribe lane region SLR located between the peripheral circuit regions PER.

The first wafer WF1 may include a first substrate 300A and peripheral circuits PC which are formed on the first substrate 300A inside the peripheral circuit regions PER. The peripheral circuits PC may include at least one transistor 1. In an embodiment, each peripheral circuit may include at least one transistor 1. An element isolation layer ISO may be formed in the first substrate 300A, and may define an active region of the transistor 1.

Subsequently, a first interconnection structure IC1 may be formed on the first substrate 300A. The first interconnection structure IC1 may be formed in the peripheral circuit region PER and the first sealing region SER1. The first interconnection structure IC1 may be formed in a first interlayer insulating layer IL1. For example, as illustrated in FIG. 3B, the first interlayer insulating layer IL1 may be formed on the first substrate 300A. The first interconnection structure IC1 may include at least one vertically extending first via 310A and at least one horizontally extending first wiring line 310B. As illustrated in the embodiment of FIG. 3B, a plurality of first vias 310A and first wiring lines may be used. A lowermost of the first vias 310A may be connected to the peripheral circuit PC. The first vias 310A may connect the first wiring lines 310B to each other. A lowermost of the first vias 310A may be in contact with the first substrate 300A. The first interconnection structure IC1 may include a conductive material such as, for example, tungsten, copper, or aluminum. The first interlayer insulating layer IL1 may include an insulating material such, as for example, an oxide.

Subsequently, first bonding pads 320 may be formed on the first interconnection structures IC1 in the peripheral circuit region PER and the first sealing region SER1. For example, the first bonding pads 320 may be formed on top of the first interconnection structures IC1 in a one to one correspondence, meaning that a single first bonding pad may be formed on top of each first interconnection structure IC1. The first bonding pads 320 may be formed in the first interlayer insulating layer IL1. At least one of the first bonding pads 320 may be connected to the peripheral circuit PC through the first interconnection structure IC1. The first bonding pads 320 may each include a conductive material such, as for example, copper.

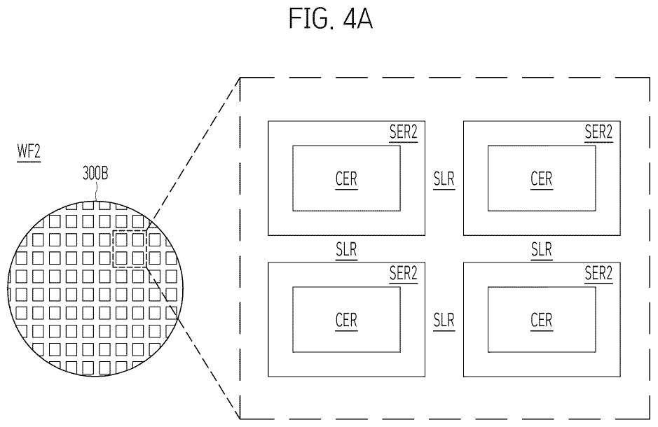

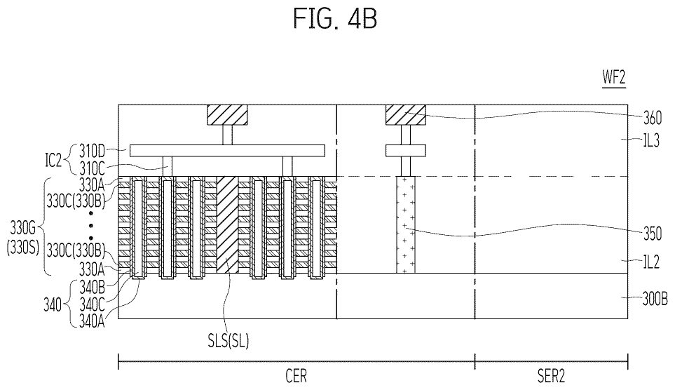

Referring to FIGS. 4A and 4B, a second wafer WF2 may be formed. For example, the second wafer WF2 may include cell regions CER and second sealing regions SER1 surrounding the cell regions CER. A scribe lane region SLR may be located between the cell regions CER.

The second wafer WF2 may include a second substrate 300B. A stack 330S may be formed over the second substrate 300B by alternately stacking first and second material layers 330A and 330B. Here, the first material layers 330A may each include an insulating material such, as for example, an oxide. The second material layers 330B may each include a sacrificial material such as, for example, a nitride. Channel structures 340 extending into the second substrate 300B through the stack 330S may be formed. Each of the channel structures 340 may include a channel layer 340A, a memory layer 340B surrounding the channel layer 340A, and an insulating core 340C located in the channel layer 340A.

Subsequently, a slit SL extending vertically through the stack 330S may be formed. The second material layers 330B of the stack 330S may be replaced with third material layers 330C through the slit SL. Consequently, a gate structure 330G including the first material layers 330A and the third material layers 330C that are alternately stacked may be defined. Here, the third material layers 330C may each include a conductive material such as tungsten. For reference, when the second material layers 330B each include a conductive material, a process of replacing the second material layers 330B with the third material layers 330C may be omitted. Subsequently, a slit structure SLS may be formed in the slit SL. The slit structure SLS may include an insulating material, a conductive material, a semiconductor material, or the like.

A second interlayer insulating layer IL2 may be formed on the second substrate 300B. For example, the second interlayer insulating layer IL2 may be formed in the cell region CER and the second sealing region SER. A contact plug 350 may be formed over the second substrate 300B. The contact plug 350 may be formed in the second interlayer insulating layer IL2. The contact plug 350 may include a conductive material such as, for example, tungsten, copper, or aluminum. The second interlayer insulating layer IL2 may include an insulating material such, as for example, an oxide or nitride.

Subsequently, a third interlayer insulating layer IL3 may be formed on the second interlayer insulating layer IL2. Subsequently, a second interconnection structure IC2 may be formed in the cell region CER. For example, the second interconnection structure IC2 connected to at least one of the channel structures 340 and the contact plug 350 may be formed. The second interconnection structure IC2 may not be formed in the second sealing region SER2. The second interconnection structure IC2 may include a vertically extended second via 310C and a horizontally extending second wiring line 310D. The second interconnection structure IC2 may include a conductive material such as, for example, tungsten, copper, or aluminum. The third interlayer insulating layer IL3 may include an insulating material such, as for example, an oxide or nitride.

Subsequently, second bonding pads 360 may be formed in the cell region CER. For example, the second bonding pads 360 connected to the second interconnection structure IC2 may be formed. The second interconnection structure IC2 may not be formed in the second sealing region SER2. The second bonding pads 360 may be formed in the third interlayer insulating layer IL3. The second bonding pads 360 may each include a conductive material such, as for example, copper.

The second and third interlayer insulating layers IL2 and IL3 may be formed in the second sealing region SER2. Structures other than the second and third interlayer insulating layers IL2 and IL3 may not be formed in the second sealing region SER2. For example, the second bonding pads 360 may not be formed in the second sealing region SER2. Accordingly, in a subsequent process, first openings for forming contact rings may be formed by etching the third and second interlayer insulating layers IL3 and IL2.

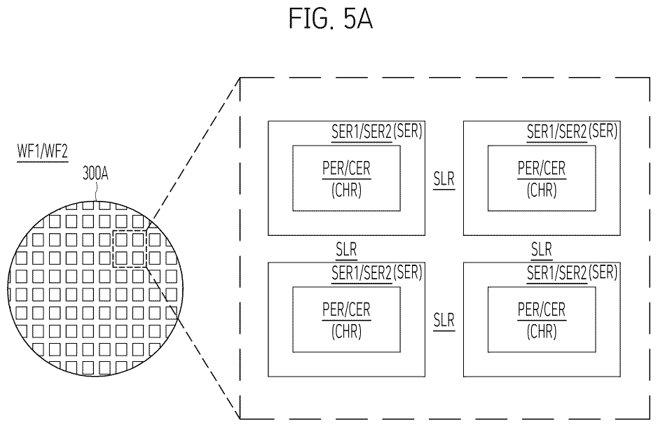

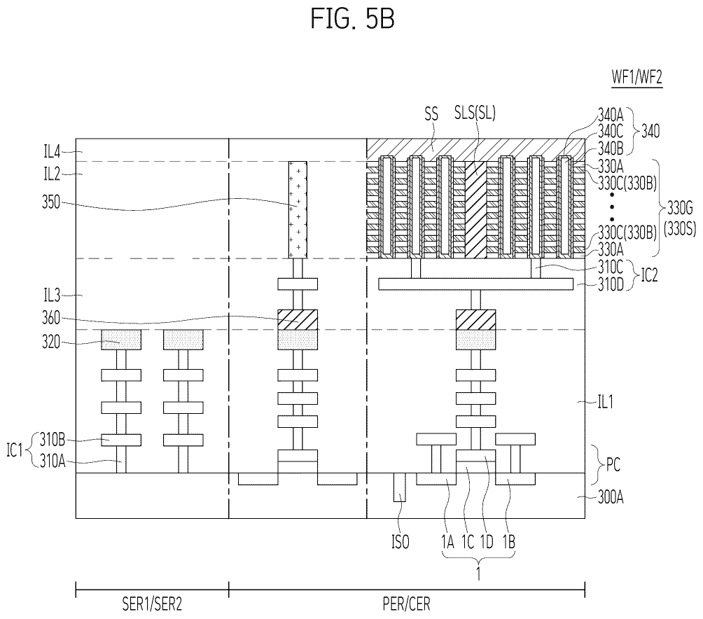

Referring to FIGS. 5A and 5B, the first wafer WF1 and the second wafer WF2 may be bonded to each other. For example, the first wafer WF1 and the second wafer WF2 may be bonded to each other so that the peripheral circuit region PER of the first wafer WF1 and the cell region CER of the second wafer WF2 face each other and the first sealing region SER1 of the first wafer WF1 and the second sealing region SER2 of the second wafer WF2 face each other. The first bonding pads 320 of the peripheral circuit region PER and the second bonding pads 360 of the cell region CER may be bonded to each other, and the first interlayer insulating layer IL1 of the first sealing region SER1 in which the first bonding pads 320 are formed and the third interlayer insulating layer IL3 of the second sealing region SER2 may be bonded to each other. Here, the peripheral circuit region PER and the cell region CER may be defined as a chip region CHR, and the first sealing region SER1 and the second sealing region SER2 may be defined as a sealing region SER.

In bonding the first and second wafers WF1 and to each other, the first and second bonding pads 320 and 360 may expand. In such a case, a delamination phenomenon may occur at a bonding interface. Bonding force at the bonding interface may become greater as an area occupied by the first interlayer insulating layer IL1 and the third interlayer insulating layer IL3 becomes greater. For example, the bonding force at the bonding interface may become greater as the area occupied by the first interlayer insulating layer IL1 and the third interlayer insulating layer IL3 becomes greater than an area occupied by the first bonding pads 320 and the second bonding pads 360 each including copper.

According to an embodiment of the present disclosure, the second bonding pads 360 may not be formed in the second sealing region SER2. In such a case, the area occupied by the first and third interlayer insulating layers IL1 and IL3 in the sealing region SER may be relatively greater than that in the chip region CHR, and the bonding force at the bonding interface in the sealing region SER may be relatively greater than that in the chip region CHR. Accordingly, even though the first bonding pads 120 expand in the process of bonding the first and second wafers WF1 and WF2 to each other, the delamination phenomenon at the bonding interface may be prevented from occurring.

Subsequently, the second substrate 300B may be removed. Subsequently, a source structure SS connected to the channel structures 340 may be formed. Before the source structure SS is formed, the channel layers 340A may be exposed by partially removing the memory layers 340B of the channel structures 340. A fourth interlayer insulating layer IL4 may be formed on the second interlayer insulating layer IL2. For example, the fourth interlayer insulating layer IL4 may be formed on the contact plug 350. The fourth interlayer insulating layer IL4 may include an insulating material such, as for example, an oxide or nitride.

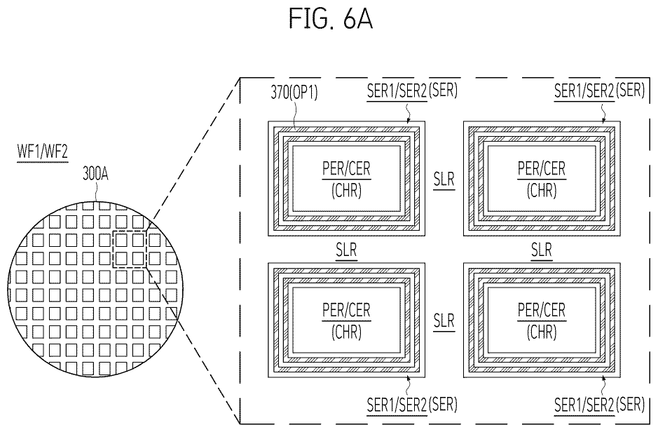

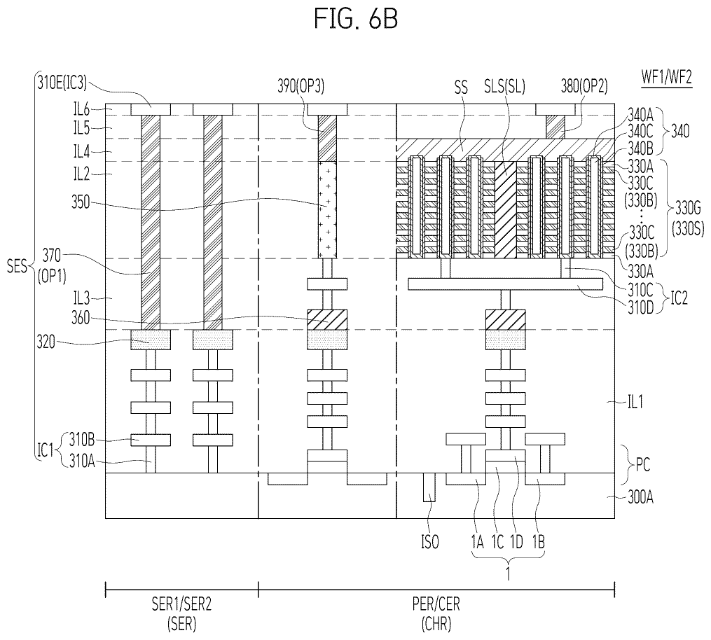

Referring to FIGS. 6A and 6B, contact rings 370 may be formed on the first bonding pads 320. First, first openings OP1 exposing the first bonding pads 320 of the first sealing region SER1 and having a closed curve shape may be formed through a fifth interlayer insulating layer IL5, the fourth interlayer insulating layer IL4, the second interlayer insulating layer IL2, and the third interlayer insulating layer IL3 of the second sealing region SER. Accordingly, the first openings OP1 may be formed in the sealing region SER surrounding the chip region CHR. Subsequently, the contact rings 370 may be formed in the first openings OP1. The contact rings 370 may each include a conductive material such as, for example, tungsten, copper, or aluminum. Before the contact rings 370 are formed, the fifth interlayer insulating layer IL5 may be formed on the fourth interlayer insulating layer IL4. The fifth interlayer insulating layer IL5 may include an insulating material such, as for example, an oxide or nitride.

A first contact via 380 connected to the source structure SS may be formed. First, a second opening OP2 exposing the source structure SS may be formed. For example, the second opening OP2 exposing the source structure SS may be formed through the fifth interlayer insulating layer IL5. Subsequently, the first contact via 380 may be formed in the second opening OP2 by filling the second opening OP2 with a conductive material such as, for example, tungsten, copper, or aluminum.

A second contact via 390 connected to the contact plug 350 may be formed. The second contact via 390 may be formed by first forming a third opening OP3 exposing the contact plug 350 through the fifth interlayer insulating layer IL5 and the fourth interlayer insulating layer IL4. Subsequently, the third opening OP3 may be filled with a conductive material such as, for example, tungsten, copper, or aluminum to form the second contact via 390.

According to an embodiment of the present disclosure, when the first openings OP1 are formed, the second opening OP2 and the third opening OP3 may be formed. When the first openings OP1 are formed, the second opening OP2 may be formed. When the first openings OP1 are formed, the third opening OP3 may also be formed. However, the embodiments of the present disclosure are not limited thereto, and, for example, the second opening OP2 and the third opening OP3 may be formed after the first openings OP1 are formed. Alternatively, after the second opening OP2 and the third opening OP3 are formed, the first openings OP1 may be formed.

When the contact rings 370 are formed, the first and second contact vias 380 and 390 may be formed. When the contact rings 370 are formed, the first contact via 380 may be formed. When the contact rings 370 are formed, the second contact via 390 may be formed. For example, a conductive material may be formed to fill the first openings OP1, the second opening OP2, and the third opening OP3. Subsequently, the contact rings 370, the first contact via 380, and the second contact via 390 may be formed by performing planarization so that an uppermost surface of the fifth interlayer insulating layer IL5 is exposed. Accordingly, the contact rings 370, the first contact via 380, and the second contact via 390 may include the same or substantially the same material. For example, the contact rings 370, the first contact via 380, and the second contact via 390 may each include a conductive material such as, for example, tungsten, copper, or aluminum.

Subsequently, a third interconnection structure IC3 may be formed. The third interconnection structure IC3 may be formed on the contact rings 370, the first contact via 380, and the second contact via 390. Here, the third interconnection structure IC3 may be formed in a sixth interlayer insulating layer IL6. The sixth interlayer insulating layer IL6 may be formed on the fifth interlayer insulating layer IL5. The third interconnection structure IC3 may include third wiring lines 310E. However, the third interconnection structure IC3 is not limited thereto, and may further include vertically extending third vias. The third interconnection structure IC3 may include a conductive material such as, for example, tungsten, copper, or aluminum.

In the sealing region SER, the third interconnection structure IC3, the contact rings 370, the first bonding pads 320, and the first interconnection structure IC1 may constitute a sealing structure SES. The sealing structure SES may protect the chip region CHR from external contamination or moisture. The sealing structure SES may prevent or reduce damage to the chip region CHR in a subsequent process.

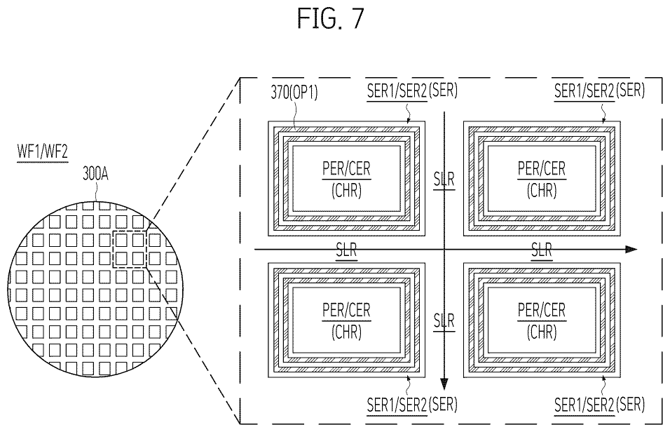

Referring to FIG. 7, the first wafer WF1 and the second wafer WF2 may be cut along the scribe lane region SLR. When the first wafer WF1 and the second wafer WF2 are cut along the scribe lane region SLR, the chip regions CHR may be separated from each other.

In a process of cutting the first wafer WF1 and the second wafer WF2, a crack may occur in the chip region CHR. According to an embodiment of the present disclosure, the contact rings 370 having a closed curve shape may be formed in the sealing region SER surrounding the chip region CHR. In addition, the third interconnection structure IC3, the contact rings 370, the first bonding pads 320, and the first interconnection structure IC1 may constitute the sealing structure SES. Accordingly, the sealing structure SES may prevent or reduce the damage to the chip region CHR. In addition, the sealing structure SES may protect the chip region CHR from external contamination or moisture after the cutting. For example, the sealing structure SES may prevent or reduce the damage to the chip region CHR from external contamination or moisture.

According to the manufacturing method described above, the second bonding pads 360 may not be formed in the second sealing region SER2. Therefore, in the process of bonding the first wafer WF1 and the second wafer WF2 to each other, the delamination phenomenon may not occur at the bonding interface.

The contact rings 370 surrounding the chip region CHR may be formed along the sealing region SER. The contact rings 370 may constitute the sealing structure SES together with the third interconnection structure IC3, the first bonding pads 320, and the first interconnection structure IC1. The sealing structure SES may protect the chip region CHR from external contamination or moisture. In addition, the sealing structure SES may prevent or reduce damage to the chip region CHR in the process of cutting the first wafer WF1 and the second wafer WF2.

Although embodiments according to the technical idea of the present disclosure have been described above with reference to the accompanying drawings, this is only for describing the embodiments according to the concept of the present disclosure, and the present disclosure is not limited to the above embodiments. Various types of substitutions, modifications, and changes for the embodiments may be made by those skilled in the art, to which the present disclosure pertains, without departing from the technical idea of the present disclosure defined in the following claims, and it should be construed that these substitutions, modifications, and changes belong to the scope of the present disclosure. Furthermore, the embodiments may be combined to form additional embodiments.

What is claimed is:

1. A semiconductor device comprising:
a substrate including a chip region and a sealing region surrounding the chip region;
first bonding pads located over the substrate;
second bonding pads located in the chip region and bonded to the first bonding pads;
an interlayer insulating layer located on the first bonding pads; and
contact rings located in the sealing region, extending through the interlayer insulating layer and connected to the first bonding pads, and each having a closed curve shape.

2. The semiconductor device of claim 1, wherein the contact rings each have a closed curve shape surrounding the chip region along the sealing region.

3. The semiconductor device of claim 1, further comprising:
a source structure located over the second bonding pads; and
a first contact via located on the source structure.

4. The semiconductor device of claim 3, wherein the contact rings each include substantially the same material as the first contact via.

5. The semiconductor device of claim 4, wherein the contact rings and the first contact via each include tungsten, copper, or aluminum.

6. The semiconductor device of claim 4, wherein uppermost surfaces of the contact rings are located at substantially the same level as an uppermost surface of the first contact via.

7. The semiconductor device of claim 1, further comprising:
a peripheral circuit located in the chip region;
a contact plug located over the peripheral circuit; and
a second contact via located on the contact plug.

8. The semiconductor device of claim 7, wherein the contact plug is electrically connected to the peripheral circuit.

9. The semiconductor device of claim 7, wherein the contact rings each include substantially the same material as the second contact via.

10. The semiconductor device of claim 9, wherein the contact rings and the second contact via each include tungsten, copper, or aluminum.

11. The semiconductor device of claim 7, wherein uppermost surfaces of the contact rings are located at substantially the same level as an uppermost surface of the second contact via.

12. The semiconductor device of claim 1, further comprising:
a gate structure located in the chip region;
channel structures extending through the gate structure; and
a source structure located on the gate structure.

13. The semiconductor device of claim 12, wherein the channel structures are connected to the source structure.

14. A manufacturing method of a semiconductor device, the manufacturing method comprising:
forming a first wafer including a peripheral circuit region and a first sealing region surrounding the peripheral circuit region and including first bonding pads located in the peripheral circuit region and the first sealing region;
forming a second wafer including a cell region and a second sealing region surrounding the cell region and including an interlayer insulating layer located in the cell region and the second sealing region and second bonding pads located in the cell region;
bonding the first wafer and the second wafer to each other so that the peripheral circuit region and the cell region face each other and the first sealing region and the second sealing region face each other;
forming first openings through the interlayer insulating layer of the second sealing region, the first openings exposing the first bonding pads of the first sealing region and each having a closed curve shape; and
forming contact rings in the first openings.

15. The manufacturing method of claim 14, wherein in the bonding of the first wafer and the second wafer to each other, the first bonding pads of the peripheral circuit region and the second bonding pads of the cell region are bonded to each other, and the first bonding pads of the first sealing region and the interlayer insulating layer of the second sealing region are bonded to each other.

16. The manufacturing method of claim 14, wherein the second wafer comprises:
a substrate;
a stack located on the substrate; and
channel structures extending into the substrate through the stack.

17. The manufacturing method of claim 16, further comprising:
removing the substrate after bonding the first wafer and the second wafer to each other;
forming a source structure connected to the channel structures;
forming a second opening exposing the source structure; and
forming a first contact via in the second opening.

18. The manufacturing method of claim 17, wherein the second opening is formed when the first openings are formed.

19. The manufacturing method of claim 17, wherein the second opening is formed after the first openings are formed.

20. The manufacturing method of claim 17, wherein the first contact via is formed when the contact rings are formed.

21. The manufacturing method of claim 17, wherein the contact rings each include substantially the same material as the first contact via.

22. The manufacturing method of claim 21, wherein the contact rings and the first contact via each include tungsten, copper, or aluminum.

23. The manufacturing method of claim 14, wherein the second wafer comprises:
a substrate; and
a contact plug located on the substrate.

24. The manufacturing method of claim 23, further comprising:
forming a third opening exposing the contact plug after bonding the first wafer and the second wafer to each other; and
forming a second contact via in the third opening.

25. The manufacturing method of claim 24, wherein the third opening is formed when the first openings are formed.

26. The manufacturing method of claim 24, wherein the third opening is formed after the first openings are formed.

27. The manufacturing method of claim 24, wherein the second contact via is formed when the contact rings are formed.

28. The manufacturing method of claim 24, wherein the contact rings each include substantially the same material as the second contact via.

29. The manufacturing method of claim 28, wherein the contact rings and the second contact via each include tungsten, copper, or aluminum.
